(19) United States
(12) Patent Application Publication
(10) Pub. No.: US 2026/0305348 A1
(43) Pub. Date: Oct. 1, 2026

(54) CRACKSTOP STRUCTURES

(71) Applicant: GlobalFoundries U.S. Inc., Malta, NY (US)

(72) Inventors: Nayden Petkov Nedev, Sofia (BG); Ivan Krasimirov Kanev, Sofia (BG); Romain Feuillette, Williston, VT (US)

(21) Appl. No.: 19/089,297

(22) Filed: Mar. 25, 2025

(51) Int. Cl. H01L 23/58; H01L 21/78; H01L 23/00

(52) U.S. Cl. CPC H10W 42/00; H10P 54/00; H10W 42/121

(57) ABSTRACT

The present disclosure relates to semiconductor structures and, more particularly, to crackstop structures and methods of manufacture. The structure includes a ring structure with multiple metal layers that surround an active region of a die. The ring structure includes adjacent legs connect together at curved corners having a radius of curvature.

### BACKGROUND

The present disclosure relates to semiconductor structures and, more particularly, to crackstop structures and methods of manufacture.

Crackstop structures are an important part of the back-end of line (BEOL) semiconductor processes. Crackstop structures, for example, are stress protection structures that surround integrated circuits on a wafer (e.g., semiconductor substrate), protecting the internal circuit inside the semiconductor chips from damage caused by the dicing (e.g., sawing) of semiconductor chips from the wafer. Further, the crackstop structures may be used to prevent moisture from penetrating into the semiconductor chips.

### SUMMARY

In an aspect of the disclosure, a structure comprises a ring structure comprising multiple metal layers that surround an active region of a die, wherein the ring structure comprises adjacent legs connect together at curved corners having a radius of curvature.

In an aspect of the disclosure, a structure comprises: a semiconductor substrate comprising a plurality of dies with active regions separated by a kerf region; and a crackstop structure that surrounds active regions of the plurality of dies, the crackstop structure comprising multiple legs that connect together in an uninterrupted manner at rounded corners.

In an aspect of the disclosure, a method comprises: forming a plurality of dies with active regions on a semiconductor substrate separated by a kerf region; and forming a crackstop structure that surrounds the active region of each of the plurality of dies, the crackstop structure formed with multiple legs connected together in an uninterrupted manner at rounded corners.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a semiconductor substrate with crackstop structures and respective fabrication processes in accordance with aspects of the present disclosure.

FIGS. 2 and 3 show crackstop structures in accordance with additional aspects of the present disclosure.

FIG. 4 shows a representative method of determining a curvature of radius of a rounded or curved corner of the crackstop structure in accordance with aspects of the present disclosure.

### DETAILED DESCRIPTION

The present disclosure relates to semiconductor structures and, more particularly, to crackstop structures and methods of manufacture. More specifically, the crackstop structures comprise rounded or curved corners which are designed and configured to reduce stress on the crackstop structure during a dicing process. Accordingly and advantageously, the rounded corners provide improved mechanical strength and distribution of stress on the crackstop structures during the dicing process. This increased mechanical stress, in turn, eliminates the propagation of unwanted cracks in the crackstop structures and thus provides improved protection of the circuitry within the crackstop structures during and after the dicing processes.

It should be understood by those of skill in the art that the crackstop structures are provided surround the active regions of a die. The crackstop structures may be provided, for example, in a kerf region of the semiconductor substrate. The kerf region will include the scribe lines which are used to separate the chips on the semiconductor substrate. For example, the scribe lines may be a guide for sawing or laser operations to separate the chips on the semiconductor substrate. During the dicing operations, though, the semiconductor substrates and crackstop structures are subjected to high mechanical stresses which may damage the crackstop structures. To increase the strength of the crackstop structures and prevent damage thereto and to the circuitry of the chip, the corners of the crackstop structures are rounded or curved as described herein.

The crackstop structures of the present disclosure can be manufactured in a number of ways using a number of different tools. In general, though, the methodologies and tools are used to form structures with dimensions in the micrometer and nanometer scale. The methodologies, i.e., technologies, employed to manufacture the crackstop structures of the present disclosure have been adopted from integrated circuit (IC) technology. For example, the structures are built on semiconductor substrates and are realized in films of material patterned by photolithographic processes on the top of a semiconductor substrate. In particular, the fabrication of the crackstop structures uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

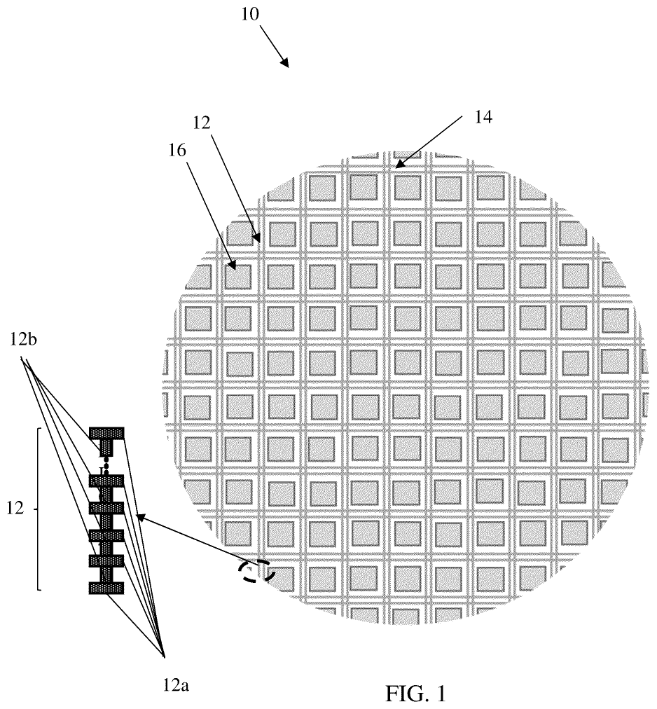

FIG. 1 shows a semiconductor substrate with crackstop structures and respective fabrication processes in accordance with aspects of the present disclosure. More specifically, FIG. 1 shows a semiconductor substrate 10 comprising metal ring structures 12, e.g., crackstop structures, within, for example, a kerf region 14 surrounding individual dies 16, e.g., chips with an active region comprising circuitry, on the semiconductor substrate 10. The ring structures 12 may comprise adjacent legs connect together at curved corners having a radius of curvature and which would completely surround the die without any interruptions.

It should be understood by those of skill in the art that scribe lines may be provided within the kerf region 14, which are used to separate the dies 16, e.g., chips, formed on the semiconductor substrate 10 at the end of semiconductor substrate processing. Hereinafter, the ring structure will be described as a crackstop feature; although it should be understood as described herein that such ring structure can be a seal ring, crackstop or a combination thereof. Preferably, the ring structure will be the outermost structure that surrounds an active region of a die 16.

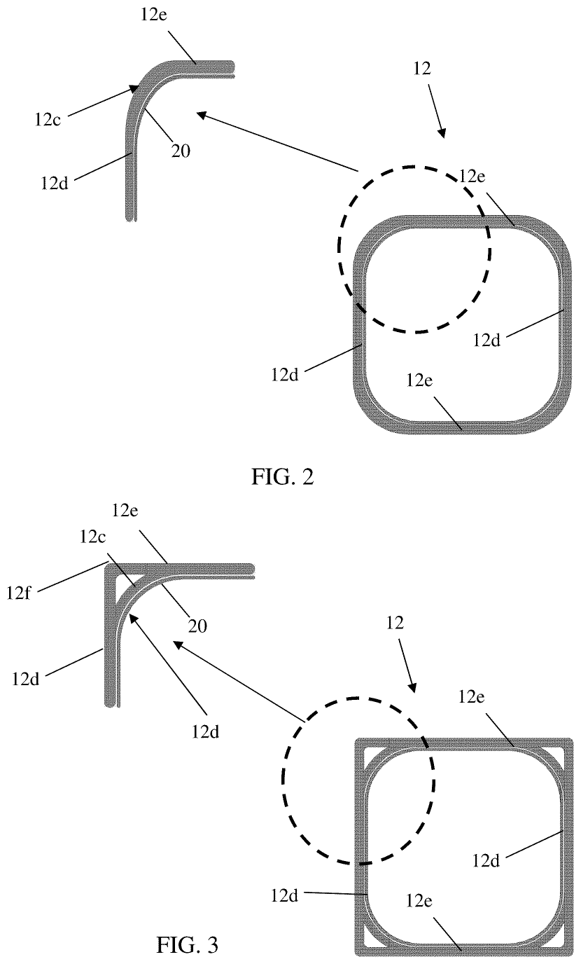

In embodiments, the crackstop structures 12 comprises several levels of interconnected metal lines 12a and vias interconnect structures 12b. In preferred embodiments, the interconnected metal lines 12a and via interconnects structures 12b extend from a surface of a semiconductor substrate to an uppermost passivation layer, e.g., interlevel dielectric material, of the dies 16. In this way, the crackstop structures 12 completely surrounds each die 16, e.g., chip, providing mechanical protection while also preventing moisture ingress into the die 16, itself. Also, as in each of the embodiments and as further shown in FIGS. 2-3, the crackstop structures 12 comprise rounded or curved corners as further described herein.

In embodiments, the metal lines 12a and vias interconnects 12b may comprise metal layers used in conventional back end of the line (BEOL) processes. For example, the metal lines 12a and vias interconnect structures 12b may be tungsten, aluminum, copper, etc., which may also be used to form wiring structures and via interconnect structures as is known in the art such that no further explanation is required for a complete understanding of the present disclosure.

The metal lines 12a and vias interconnect structures 12b can be a plurality of stacked metal interconnections, e.g., layers, formed by conventional CMOS technologies. More specifically, at each wiring layer of the die, metal layers can be fabricated in a stacked arrangement, one on top of another, using conventional lithography, etching and deposition methods known to those of skill in the art. For example, a resist formed over a first insulator layer is exposed to energy (light) to form a pattern (opening). An etching process with a selective chemistry, e.g., reactive ion etching (RIE), can be used to form one or more trenches in the insulator material through the openings of the resist. Following resist removal by a conventional oxygen ashing process or other known stripants, metal material or combinations thereof, e.g., copper, aluminum, metal alloys, etc., can be deposited by any conventional deposition processes, e.g., chemical vapor deposition (CVD). Any residual material on the surface of the insulator material can be removed. This same process can be repeated for all subsequent metal layers to form a crackstop structure 12.

As shown in FIG. 2, the crackstop structure 12 includes a plurality of rounded or curved corners 12c placed between respective vertical legs 12d and horizontal legs 12e of the crackstop structure 12. It should be understood by those of skill in the art that the plurality of rounded or curved corners 12c are not beveled or chamfered corners, which would not adequately reduce the mechanical stress on the crackstop structure 12 during the dicing process.

It should be recognized that beveled or chamfered corners include edges that are not rounded. For example, a chamfer is a beveled edge or transitional slope between two surfaces or faces of an object which are created at a 45° angle, but the angle can vary depending on the application. A chamfer is a transitional edge between two faces of an object. Sometimes defined as a form of bevel, it is often created at a 45° angle between two adjoining right-angled faces. In comparison, the rounded or curved corners do not have an angle and, instead, have a radius of curvature. In differential geometry, the radius of curvature, R, is the reciprocal of the curvature. For a curve, it equals the radius of the circular arc which best approximates the curve at that point. For surfaces, the radius of curvature is the radius of a circle that best fits a normal section or combinations thereof.

Although FIG. 2 shows a square-like structure with the rounded or curved corners 12c, it should be understood that the crackstop structure 12 may be any polygonal shape with each adjacent leg 12d, 12e connected together at the rounded or curved corners 12c. It should also be understood by those of skill in the art that the crackstop structure 12 may be representative of an inner seal ring structure (represented by reference numeral 20 in the exploded view of FIG. 2) or a combination of the crackstop structure 12 and the inner seal ring structure 20. In this configuration, the combination of the crackstop structure 12 and the inner seal ring structure 20 should preferably have the same shape, with the rounded or curved corners; although different shapes are also contemplated herein.

FIG. 3 shows another example of the crackstop structure 12 in accordance with aspects of the present disclosure. As shown in FIG. 3, the crackstop structure 12 includes a plurality of rounded or curved corners 12c placed between the respective vertical legs 12d and horizontal legs 12e of the crackstop structure 12. In addition, the crackstop structure 12 includes extensions of the vertical legs 12d and horizontal legs 12e which are connected together as shown at reference numeral 12f. The extensions preferable also connect at a rounded or curved corner 12f, but at a different radius of curvature of the rounded or curved corner 12c. It is also contemplated that the extensions of the vertical legs 12d and horizontal legs 12e may be connected together at a right angle.

It should be understood by those of skill in the art that the plurality of rounded or curved corners 12c (and, in embodiments, corner 12f) are not beveled or chamfered corners, which would not adequately reduce the mechanical stress on the crackstop structure 12 during the dicing process. In additional aspects of the present disclosure, the right angle 12f may include the rounded or curved feature as described herein, but with a different radius of curvature, e.g., less than a 90 degree connection.

Moreover, as with FIG. 2, the square-like structure with the rounded or curved corners 12c may be any polygonal shape with each of the adjacent legs 12d, 12e connected together with or at the rounded or curved corners 12c. It should also be understood by those of skill in the art that the crackstop structure 12 may be representative of an inner seal ring structure (represented by reference numeral 20 in the exploded view of FIG. 3) or a combination of the crackstop structure 12 and the inner seal ring structure 20. As in each of the embodiments, the crackstop structure 12 and the inner seal ring structure 20 may also have the same shape or different shape (with the rounded or curved corners 12c).

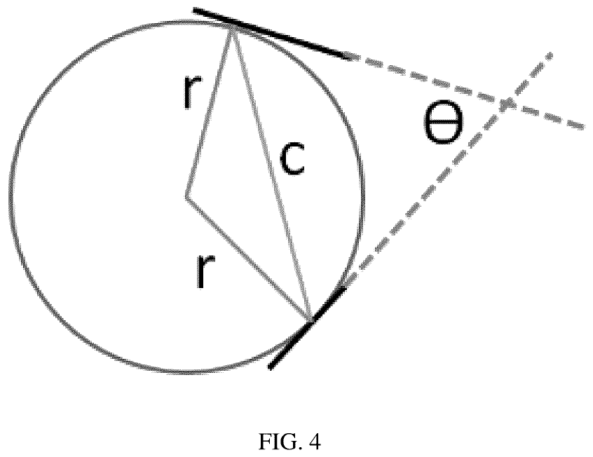

FIG. 4 shows a representative method of determining radius a of curvature of a corner of the crackstop structure in accordance with aspects of the present disclosure. It should be understood that other radius of curvature can also be used for the rounded or curved corners 12c and, as such, there no limiting feature should be attached to the manner of determining the curve or rounded corners 12c.

In FIG. 4, for example, to determine the radius of curvature, a circle is derived, such that, both edges of any given edge pair, are tangents to this circle. The radius “x” of the derived circle is the radius of curvature for this edge pair. The distance “c” between the edges and the angle between the edges are related to the radius “x” by the following equation:

$$C = 2 \times r \times cos ( \frac{θ}{2} ) .$$

The crackstop structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw semiconductor substrate form (that is, as a single semiconductor substrate that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising a ring structure comprising multiple metal layers that surround an active region of a die, wherein the ring structure comprises adjacent legs connect together at curved corners having a radius of curvature.

2. The structure of claim 1, wherein the ring structure comprises one of a crackstop structure and a seal ring structure.

3. The structure of claim 1, wherein the ring structure comprises a combination of a crackstop structure and a seal ring structure.

4. The structure of claim 3, wherein the crackstop structure is an outermost structure that completely surrounds the active region of the die.

5. The structure of claim 3, wherein the crackstop structure and the seal ring structure comprise a same shape.

6. The structure of claim 3, wherein the crackstop structure and the seal ring structure comprise a different shape.

7. The structure of claim 1, wherein the curved corners are rounded corners.

8. The structure of claim 1, wherein the curved corners are non-beveled corners.

9. The structure of claim 1, wherein the curved corners are non-chamfered corners.

10. The structure of claim 1, wherein the metal layers comprise multiple wiring lines and via interconnect structures.

11. A structure comprising:
a semiconductor substrate comprising a plurality of dies with active regions separated by a kerf region; and
a crackstop structure that surrounds active regions of the plurality of dies, the crackstop structure comprising multiple legs that connect together in an uninterrupted manner at rounded corners.

12. The structure of claim 11, wherein crackstop structure comprises a combination of an outer crackstop feature and an inner seal ring feature.

13. The structure of claim 12, wherein the outer crackstop feature and the inner seal ring feature comprise a same shape.

14. The structure of claim 12, wherein the outer crackstop feature and the inner seal ring feature comprise a different shape.

15. The structure of claim 12, wherein the rounded corners are non-beveled corners.

16. The structure of claim 12, wherein the rounded corners are non-chamfered corners.

17. The structure of claim 12, wherein the multiple legs and the crackstop structure comprises multiple wiring lines and via interconnect structures.

18. The structure of claim 12, wherein the multiple legs comprise extensions which connect together outside of the rounded corners.

19. The structure of claim 18, wherein the extensions connect together at curved corners with a different radius of curvature from the radius of curvature of the rounded corners.

20. A method comprising:
forming a plurality of dies with active regions on a semiconductor substrate separated by a kerf region; and
forming a crackstop structure that surrounds the active region of each of the plurality of dies, the crackstop structure formed with multiple legs connected together in an uninterrupted manner at rounded corners.
